(19) United States
(12) Patent Application Publication
(10) Pub. No.: US 2009/0027758 A1
(43) Pub. Date: Jan. 29, 2009

(54) Reversible Coloring and Decoloring Solid-State Device, a Reversible Conductive Property Changing Solid-State Device, a Reversible Refractive Index Changing Solid-State Device, a Nonradiative Display Device, a Conducting Path Device and a Light Waveguide Device

(75) Inventors: Nobuyoshi Koshida, Tokyo (JP); Hideo Yoshimura, Tokyo (JP)

Correspondence Address: KANESAKA BERNER AND PARTNERS LLP, 1700 DIAGONAL RD, SUITE 310, ALEXANDRIA, VA, 22314-2848, US

(73) Assignee: NATIONAL UNIVERSITY CORPORATION TOKYO UNIVERSITY OF AGRICULTURE AND TECHNOLOGY, Fuchu-shi (JP)

(21) Appl. No.: 11/886,584

(22) PCT Filed: Mar. 20, 2006
(86) PCT No.: PCT/JP2006/306065

§ 371 Date: Jan. 17, 2008

(30) Foreign Application Priority Data
Mar. 19, 2005 (JP) 2005-118885

(51) Int. Cl. G02F 1/153; H01L 29/66; G02F 1/29; G02F 1/295

(52) U.S. Cl. 359/274; 359/265; 257/212; 359/315; 385/8

(57) ABSTRACT

A reversible coloring and deccoloring solid-state device includes a solid-state electrolyte film and a coloring and decoloring film which colors or decolors the coloring and decoloring film reversibly by applying an electric field. A barrier thin film is inserted between the solid-state electrolyte film and the coloring and decoloring film. The barrier thin film comprises at least one layer which is formed by a material having a band gap energy, functions as a barrier for the carrier movement, and has a thickness of 7 nm to 7±2 nm which does not prevent ion conduction. The coloring and decoloring speed is 0.1 seconds to 0.3 seconds by a voltage driving.

### BACKGROUND OF THE INVENTION AND RELATED ART STATEMENT

This invention relates to a reversible coloring and decoloring solid-state device, a reversible conductive property changing solid-state device, a reversible refractive index changing solid-state device, and the applications of these solid-state devices, e.g. a nonradiative display device, a conducting path device and a light waveguide device, wherein the optical and electric properties (the characteristics of coloring and decoloring, conductive property change, and refractive index change) of a WO₃ film are reversibly changed rapidly by applying an electric field or irradiating a light with an application of an electric field, and more specifically, a technique for reversibly changing the optical and electric properties which can dramatically improve the characteristics of reversibly changing the above mentioned optical and electric properties and the reliability while the electrolyte for supplying ions to the WO₃ film is formed by a solid-state system.

The optical and electric properties of a kind of solid-state materials significantly change by inserting a different kind of atoms into the interstitial gaps by electric excitation or optical excitation. If the inserted atoms can be electrically pulled out from the interstitial gaps and the original condition can be recovered, the optical and electric application can be expanded.

Electrochromic (EC) devices are known as the typical devices which have this effect. EC devices are formed by contacting a thin film of a transition metal compound film with an electrolyte, and the EC devices are colored by applying an electric field of a polarity and are decolored by applying an electric field of the opposite polarity.

The coloring and decoloring are reversible and such coloring and decoloring can be also caused by irradiating an external light to the contacting portion of the transition metal compound film and the electrolyte.

FIG. 1 shows the structure and operation of a prior art EC device. In FIG. 1, the EC device 9 comprises the amorphous WO₃ (a—WO₃) thin film 91 and the electrolyte 92. When a negative (−) voltage is applied to the back side electrode (acting electrode 931) of the WO₃ thin film 91 and a positive (+) voltage is applied to the back side electrode (opposing electrode 932), positive ions M⁺ (M is, e.g. H, Li, Na) are injected from the electrolyte 92, and at the same time, an electron e⁻ is injected into the WO₃ thin film 91.

As a result of this operation, an element M is inserted into the gap in the main lattice of the WO₃, and a nonstoichiometric compound Mx WO₃ which is called tungsten bronze is formed. Where the value of x changes from 0 to 1 depending on the amount of the inserted element M, and the color changes from dark blue to golden yellow depending on the value x. When the value x is large it has a metallic characteristic, and when the value x is small it becomes a semiconductor or an insulator.

In this condition, if a voltage of the opposite polarity is applied to the device 9, positive ions M⁺ and electrons e⁻ are pulled out from the tungsten bronze, and it returns to the original WO₃ thin film 91. The aforementioned reversible process is described by the following equation.

WO₃+xM⁺+xe⁻ [symbol] MxWO₃(0≦x≦1)

The inserted element M functions as a color center optically and a donor electrically.

### SUMMARY OF THE INVENTION

Applications of EC devices to optical devices are expected because they can change the color (from transparent to the colored condition) and the refraction index optically and the conductive property (from insulating to conductive) electrically.

However they are not yet practical because the reliability is still low and the usage environment is limited when a solution system electrolyte is used as the electrolyte 92 for the EC device 9 shown in FIG. 1. Therefore it is desirable in view of device application to use a solid-state system electrolyte (a solid-state system electrolyte film) as the electrolyte 92.

FIGS. 2(A), (B) show energy band charts of EC device 9 when a solid-state electrolyte film is used as the electrolyte 92. FIG. 2(A) shows the case of no voltage is applied between the acting electrode 931 and the opposing electrode 932. FIG. 2(B) shows the case of a forward bias voltage V_{b} is applied between the acting electrode 931 and the opposing electrode 932. As shown in FIG. 2(B), when a forward bias voltage V_{b} is applied between the acting electrode 931 and the opposing electrode 932 (for setting the acting electrode 931 to the negative polarity and the opposing electrode 932 to the positive polarity), the Fermi level E_{f} changes by the electrostatic potential V_{b} and a coloring phenomenon occurs.

The coloring phenomenon occurs by the following two processes.
(1) Protons (H⁺) in the electrolyte 92 drift to the side of the WO₃ thin film 91 directly and are neutralized with the injected electrons e⁻, and the WO₃ changes to HxWO₃.
(2) Holes h⁺ in the electrolyte 92 diffuse to the side of WO₃ thin film 91, the water molecules (H₂O) are oxidized on the boundary face between the WO₃ thin film 91 and the electrolyte 92, and the protons (H⁺) are produced. Then, the protons (H⁺) diffuse into the WO₃ and reach the gaps in the main lattice and are neutralized with the injected electrons e⁻, and the WO₃ changes to H×WO₃.

The rate controlling factors for the coloring process are the proton mobility in the electrolyte 92 in case of the drifting of (1) and the oxidization reaction rate of the water molecules by the holes h⁺ and the diffusion coefficient of the protons (H⁺) in case of the diffusion of (2).

However the reaction by the drifting of (1) is slow, and the reaction by the diffusion of (2) is also slow, an EC device using a solid-state system electrolyte as well as an EC device using a solution system electrolyte is not yet put into practical use.

Japanese Laid-open Patent Application (Tokkai-Syo 57-73749) discloses a technique for positioning an insulator film between the WO₃ thin film 91 and the electrolyte 92. This technique improves the holding time of coloring, and the holding time can be from several minutes to a few months by an insulator film with 5-200 nm thickness. However this technique cannot achieve the high seed coloring and it is not practical.

The present invention was made to resolve the aforementioned problems, and the purpose of the present invention is to provide a reversible coloring and decoloring solid-state device, a reversible conductive property changing solid-state device, a reversible refractive index changing solid-state device, and the applications of these solid-state devices, e.g. a nonradiative display device, a conducting path device and a light waveguide device, which can dramatically improve the reversible changing characteristics (especially, the speed performance) of the optical and electric properties and the reliability while the electrolyte for supplying ions to the WO₃ film is formed by a solid-state system.

(1) A reversible coloring and deccoloring solid-state device comprising a solid-state electrolyte film and a coloring and decoloring film which colors or decolors the coloring and decoloring film reversibly by applying an electric field, wherein

a barrier thin film being inserted between the solid-state electrolyte film and the coloring and decoloring film, the barrier thin film comprises at least one layer which is formed by a material having a band gap energy,

the barrier thin film has a thickness of the range between 7 nm and 7±2 nm,

the device is driven by a voltage (for example, 3V) so that the coloring speed is from 0.1 seconds to 0.3 seconds.

When the band gap energy of the barrier thin film is larger than the band gap energy of the coloring and decoloring film, the coloring speed becomes faster, and when the band gap energy of the barrier thin film is smaller than the band gap energy of the coloring and decoloring film, the coloring speed becomes slower. When the band gap energy of the barrier thin film is larger than the band gap energy of the solid-state electrolyte film, the coloring speed becomes faster, and when the band gap energy of the barrier thin film is smaller than the band gap energy of the solid-state electrolyte film, the coloring speed becomes slower.

(2) A reversible coloring and deccoloring solid-state device according to (1), wherein the band gap energy of the barrier thin film is larger than the band gap energy of the material of any of the films.
(3) A reversible coloring and deccoloring solid-state device comprising a solid-state electrolyte film and a coloring and decoloring film which colors the coloring and decoloring film by irradiating a light and decolors the colored coloring and decoloring film reversibly, wherein

a barrier thin film being inserted between the solid-state electrolyte film and the coloring and decoloring film, the barrier thin film comprises at least one layer which is formed by a material having a band gap energy,

the barrier thin film has a thickness of the range between 7 nm and 7±2 nm,

the device is driven by a voltage (for example, 3V) so that the coloring speed is from 0.1 seconds to 0.3 seconds.

When the band gap energy of the barrier thin film is larger than the band gap energy of the coloring and decoloring film, the coloring speed becomes faster, and when the band gap energy of the barrier thin film is smaller than the band gap energy of the coloring and decoloring film, the coloring speed becomes slower. When the band gap energy of the barrier thin film is larger than the band gap energy of the solid-state electrolyte film, the coloring speed becomes faster, and when the band gap energy of the barrier thin film is smaller than the band gap energy of the solid-state electrolyte film, the coloring speed becomes slower.

(4) A reversible coloring and deccoloring solid-state device according to (3), wherein the band gap energy of the barrier thin film is larger than the band gap energy of the material of any of the films.
(5) A reversible coloring and deccoloring solid-state device comprising a solid-sate electrolyte film and a color changing film, and changing the colored condition of the color changing film reversibly by applying an electric field, wherein

a barrier thin film being inserted between the solid-state electrolyte film and the color changing, the barrier thin film comprises at least one layer which is formed by a material having a band gap energy,

the barrier thin film has a thickness of the range between 7 nm and 7±2 nm,

the device is driven by a voltage (for example, 3V) so that the coloring speed is from 0.1 seconds to 0.3 seconds.

When the band gap energy of the barrier thin film is larger than the band gap energy of the color changing film, the coloring speed becomes faster, and when the band gap energy of the barrier thin film is smaller than the band gap energy of the color changing film, the coloring speed becomes slower. When the band gap energy of the barrier thin film is larger than the band gap energy of the solid-state electrolyte film, the coloring speed becomes faster, and when the band gap energy of the barrier thin film is smaller than the band gap energy of the solid-state electrolyte film, the coloring speed becomes slower.

(6) A reversible coloring and deccoloring solid-state device according to (5),

wherein the band gap energy of the barrier thin film is larger than the band gap energy of the material of any of the films.

(7) A reversible coloring and deccoloring solid-state device comprising a solid-sate electrolyte film and a color changing film, and changing the colored condition of the color changing film reversibly by irradiating a light and applying an electric field, wherein

a barrier thin film being inserted between the solid-state electrolyte film and the color changing film, the barrier thin film comprises at least one layer which is formed by a material having a band gap energy,

the barrier thin film has a thickness of the range between 7 nm and 7±2 nm,

the device is driven by a voltage (for example, 3V) so that the coloring speed is from 0.1 seconds to 0.3 seconds.

When the band gap energy of the barrier thin film is larger than the band gap energy of the color changing film, the coloring speed becomes faster, and when the band gap energy of the barrier thin film is smaller than the band gap energy of the color changing film, the coloring speed becomes slower. When the band gap energy of the barrier thin film is larger than the band gap energy of the solid-state electrolyte film, the coloring speed becomes faster, and when the band gap energy of the barrier thin film is smaller than the band gap energy of the solid-state electrolyte film, the coloring speed becomes slower.

(8) A reversible coloring and deccoloring solid-state device according to (7), wherein the band gap energy of the barrier thin film is larger than the band gap energy of the material of any of the films.
(9) A reversible conductive property changing solid-state device comprising a solid-sate electrolyte film and a conductive property changing film, and making the conductive property changing film conductive or insulating reversibly by applying an electric field, wherein

a barrier thin film being inserted between the solid-state electrolyte film and the conductive property changing film, the barrier thin film comprises at least one layer which is formed by a material having a band gap energy,

the barrier thin film has a thickness of the range between 7 nm and 7±2 nm,

the device is driven in the direction that the conductivity becomes higher by a voltage (for example, 3V) so that the conductive property changing speed is from 0.1 seconds to 0.3 seconds.

When the band gap energy of the barrier thin film is larger than the band gap energy of the conductive property changing film, the conductive property change (change from a low conductive property to a high conductive property) becomes faster, and when the band gap energy of the barrier thin film is smaller than the band gap energy of the conductive property changing film, the conductive property change becomes slower. When the band gap energy of the barrier thin film is larger than the band gap energy of the solid-state electrolyte film, the conductive property change (change from a high conductive property to a low conductive property) becomes faster, and when the band gap energy of the barrier thin film is smaller than the band gap energy of the solid-state electrolyte film, the conductive property change becomes slower.

(10) A reversible conductive property changing solid-state device according to (9), wherein the band gap energy of the barrier thin film is larger than the band gap energy of the material of any of the films.
(11) A reversible conductive property changing solid-state device comprising a solid-sate electrolyte film and a conductive property changing film, and making the conductive property changing film conductive by irradiating a light and making the conductive property changing film insulating by applying an electric field reversibly, wherein

a barrier thin film being inserted between the solid-state electrolyte film and the conductive property changing film, the barrier thin film comprises at least one layer which is formed by a material having a band gap energy,

the barrier thin film has a thickness of the range between 7 nm and 7±2 nm,

the device is driven in the direction that the conductive property increases by a voltage (for example, 3V) so that the conductive property changing speed is from 0.1 seconds to 0.3 seconds.

When the band gap energy of the barrier thin film is larger than the band gap energy of the conductive property changing film, the conductive property change (change from a low conductive property to a high conductive property) becomes faster, and when the band gap energy of the barrier thin film is smaller than the band gap energy of the conductive property changing film, the conductive property change becomes slower. When the band gap energy of the barrier thin film is larger than the band gap energy of the solid-state electrolyte film, the conductive property change (change from a high conductive property to a low conductive property) becomes faster, and when the band gap energy of the barrier thin film is smaller than the band gap energy of the solid-state electrolyte film, the conductive property change becomes slower.

(12) A reversible conductive property changing solid-state device according to (11), wherein the band gap energy of the barrier thin film is larger than the band gap energy of the material of any of the films.
(13) A reversible conductive property changing solid-state device comprising a solid-sate electrolyte film and a conductive property changing film, and changing the conductive property of the conductive property changing film by applying an electric field reversibly, wherein

a barrier thin film being inserted between the solid-state electrolyte film and the conductive property changing film, the barrier thin film comprises at least one layer which is formed by a material having a band gap energy,

the barrier thin film has a thickness of the range between 7 nm and 7±2 nm,

the device is driven in the direction that the conductive property increases by a voltage (for example, 3V) so that the conductive property changing speed is from 0.1 seconds to 0.3 seconds.

When the band gap energy of the barrier thin film is larger than the band gap energy of the conductive property changing film, the conductive property change (change from a low conductive property to a high conductive property) becomes faster, and when the band gap energy of the barrier thin film is smaller than the band gap energy of the conductive property changing film, the conductive property change becomes slower. When the band gap energy of the barrier thin film is larger than the band gap energy of the solid-state electrolyte film, the conductive property change (change from a high conductive property to a low conductive property) becomes faster, and when the band gap energy of the barrier thin film is smaller than the band gap energy of the solid-state electrolyte film, the conductive property change becomes slower.

(14) A reversible conductive property changing solid-state device according to (13), wherein the band gap energy of the barrier thin film is larger than the band gap energy of the material of any of the films.
(15) A reversible conductive property changing solid-state device comprising a solid-sate electrolyte film and a conductive property changing film, and reversibly changing the conductive property of the conductive property changing film by applying an electric field and irradiating a light, wherein

a barrier thin film being inserted between the solid-state electrolyte film and the conductive property changing film, the barrier thin film comprises at least one layer which is formed by a material having a band gap energy,

the barrier thin film has a thickness of the range between 7 nm and 7±2 nm,

the device is driven in the direction that the conductive property increases by a voltage (for example, 3V) so that the conductive property changing speed is from 0.1 seconds to 0.3 seconds.

When the band gap energy of the barrier thin film is larger than the band gap energy of the conductive property changing film, the conductive property change (change from a low conductive property to a high conductive property) becomes faster, and when the band gap energy of the barrier thin film is smaller than the band gap energy of the conductive property changing film, the conductive property change becomes slower. When the band gap energy of the barrier thin film is larger than the band gap energy of the solid-state electrolyte film, the conductive property change (change from a high conductive property to a low conductive property) becomes faster, and when the band gap energy of the barrier thin film is smaller than the band gap energy of the solid-state electrolyte film, the conductive property change becomes slower.

(16) A reversible conductive property changing solid-state device according to (15), wherein the band gap energy of the barrier thin film is larger than the band gap energy of the material of any of the films.
(17) A reversible refractive index changing solid-state device comprising a solid-sate electrolyte film and a refractive index changing film, and reversibly changing the refractive index of the refractive index changing film from a first refractive index to a second refractive index or from the second refractive index to the first refractive index reciprocally by applying an electric field, wherein

a barrier thin film being inserted between the solid-state electrolyte film and the refractive index changing film, the barrier thin film comprises at least one layer which is formed by a material having a band gap energy,

the barrier thin film has a thickness of the range between 7 nm and 7±2 nm,

the device is driven in the direction that the refractive index increases by a voltage (for example, 3V) so that the refractive index changing speed is from 0.1 seconds to 0.3 seconds.

When the band gap energy of the barrier thin film is larger than the band gap energy of the refractive index changing film, the refractive index change (change from a low refractive index to a high refractive index) becomes faster, and when the band gap energy of the barrier thin film is smaller than the band gap energy of the refractive index changing film, the refractive index change becomes slower. When the band gap energy of the barrier thin film is larger than the band gap energy of the solid-state electrolyte film, the refractive index change (change from a high refractive index to a low refractive index) becomes faster, and when the band gap energy of the barrier thin film is smaller than the band gap energy of the solid-state electrolyte film, the refractive index change becomes slower.

(18) A reversible refractive index changing solid-state device according to (17), wherein the band gap energy of the barrier thin film is larger than the band gap energy of the material of any of the films.
(19) A reversible refractive index changing solid-state device comprising a solid-sate electrolyte film and a refractive index changing film, and reversibly changing the refractive index of the refractive index changing film by irradiating a light and putting the refractive index of the refractive index changed refractive index changing film back to the original refractive index by applying an electric field, wherein

a barrier thin film being inserted between the solid-state electrolyte film and the refractive index changing film, the barrier thin film comprises at least one layer which is formed by a material having a band gap energy,

the barrier thin film has a thickness of the range between 7 nm and 7±2 nm,

the device is driven in the direction that the refractive index increases by a voltage (for example, 3V) so that the refractive index changing speed is from 0.1 seconds to 0.3 seconds.

When the band gap energy of the barrier thin film is larger than the band gap energy of the refractive index changing film, the refractive index change (change from a low refractive index to a high refractive index) becomes faster, and when the band gap energy of the barrier thin film is smaller than the band gap energy of the refractive index changing film, the refractive index change becomes slower. When the band gap energy of the barrier thin film is larger than the band gap energy of the solid-state electrolyte film, the refractive index change (change from a high refractive index to a low refractive index) becomes faster, and when the band gap energy of the barrier thin film is smaller than the band gap energy of the solid-state electrolyte film, the refractive index change becomes slower.

(20) A reversible refractive index changing solid-state device according to (19), wherein the band gap energy of the barrier thin film is larger than the band gap energy of the material of any of the films.
(21) A reversible refractive index changing solid-state device comprising a solid-sate electrolyte film and a refractive index changing film, and reversibly changing the refractive index of the refractive index changing film by applying an electric field, wherein

a barrier thin film being inserted between the solid-state electrolyte film and the refractive index changing film, the barrier thin film comprises at least one layer which is formed by a material having a band gap energy,

the barrier thin film has a thickness of the range between 7 nm and 7±2 nm,

the device is driven in the direction that the refractive index increases by a voltage (for example, 3V) so that the refractive index changing speed is from 0.1 seconds to 0.3 seconds.

When the band gap energy of the barrier thin film is larger than the band gap energy of the refractive index changing film, the refractive index change (change from a low refractive index to a high refractive index) becomes faster, and when the band gap energy of the barrier thin film is smaller than the band gap energy of the refractive index changing film, the refractive index change becomes slower. When the band gap energy of the barrier thin film is larger than the band gap energy of the solid-state electrolyte film, the refractive index change (change from a high refractive index to a low refractive index) becomes faster, and when the band gap energy of the barrier thin film is smaller than the band gap energy of the solid-state electrolyte film, the refractive index change becomes slower.

(22) A reversible refractive index changing solid-state device according to (21), wherein the band gap energy of the barrier thin film is larger than the band gap energy of the material of any of the films.
(23) A reversible refractive index changing solid-state device comprising a solid-sate electrolyte film and a refractive index changing film, and reversibly changing the refractive index of the refractive index changing film by irradiating a light and applying an electric field, wherein

a barrier thin film being inserted between the solid-state electrolyte film and the refractive index changing film, the barrier thin film comprises at least one layer which is formed by a material having a band gap energy,

the barrier thin film has a thickness of the range between 7 nm and 7±2 nm,

the device is driven in the direction that the refractive index increases by a voltage (for example, 3V) so that the refractive index changing speed is from 0.1 seconds to 0.3 seconds.

When the band gap energy of the barrier thin film is larger than the band gap energy of the refractive index changing film, the refractive index change (change from a low refractive index to a high refractive index) becomes faster, and when the band gap energy of the barrier thin film is smaller than the band gap energy of the refractive index changing film, the refractive index change becomes slower. When the band gap energy of the barrier thin film is larger than the band gap energy of the solid-state electrolyte film, the refractive index change (change from a high refractive index to a low refractive index) becomes faster, and when the band gap energy of the barrier thin film is smaller than the band gap energy of the solid-state electrolyte film, the refractive index change becomes slower.

(24) A reversible refractive index changing solid-state device according to (23), wherein the band gap energy of the barrier thin film is larger than the band gap energy of the material of any of the films.
(25) A nonradiative display device, wherein the reversible coloring and decoloring solid-state device according to either one of (1) to (8) is formed on a semiconductor substrate, a glass substrate or a plastic substrate as an array, the reversible coloring and decoloring solid-state device or a group of the coloring and decoloring solid-state devices is used as one pixel. The nonradiative display device can be configured as a back light display or a reflective display.
(26) A conducting path device, wherein the reversible conductive property changing solid-state device according to (9), (10), (13) or (14) is formed on a semiconductor substrate, a glass substrate or a plastic substrate in an arbitrary pattern,

the conductive property of the conductive property changing film is controlled by applying an electric field.

(27) A conducting path device, wherein the reversible conductive property changing solid-state device according to (11), (12), (15) or (16) is formed on a semiconductor substrate, a glass substrate or a plastic substrate in an arbitrary pattern,

the conductive property of the conductive property changing film is controlled by irradiating a light and applying an electric field.

(28) A light waveguide device, wherein the reversible refractive index changing solid-state device according to (17), (18), (21) or (22) is formed on a semiconductor substrate, a glass substrate or a plastic substrate in an arbitrary pattern,

the refractive index changing film is formed as a core layer of the light waveguide and the refractive index of the refractive index changing film is controlled by applying an electric field.

(29) A light waveguide device, wherein the reversible refractive index changing solid-state device according to (19), (20), (23) or (24) is formed on a semiconductor substrate, a glass substrate or a plastic substrate in an arbitrary pattern,

the refractive index changing film is formed as a core layer of the light waveguide and the refractive index of the refractive index changing film is controlled by irradiating a light and applying an electric field.

According to the present invention, the following methods can be implemented.

(A1) A method for coloring and decoloring a reversible coloring and decoloring solid-state device comprising a solid-state electrolyte film and a coloring and decoloring film, which colors or decolors the coloring and decoloring solid-state device reversibly by applying an electric field, wherein

a barrier thin film is inserted between the solid-state electrolyte film and the coloring and decoloring film, the barrier thin film comprises at least one layer which is formed by a material having a band gap energy, has a thickness of 7 nm to 7±2 nm, does not prevent ion conduction, and prevents carrier movement,

the coloring and decoloring speed is 0.1 seconds to 0.3 seconds by a voltage driving.

(A2) A method for coloring and decoloring a reversible coloring and decoloring solid-state device comprising a solid-state electrolyte film and a color changing film, which colors or decolors the coloring and decoloring solid-state device reversibly by irradiating a light, wherein

a barrier thin film is inserted between the solid-state electrolyte film and the coloring and decoloring film, the barrier thin film comprises at least one layer which is formed by a material having a band gap energy, has a thickness of 7 nm to 7±2 nm, does not prevent ion conduction, and prevents carrier movement,

the coloring and decoloring speed is 0.1 seconds to 0.3 seconds by a voltage driving.

(A3) A method for changing the color of a reversible color changing solid-state device comprising a solid-state electrolyte film and a color changing film, which reversibly changes the colored condition of the color changing film by applying an electric field, wherein

a barrier thin film is inserted between the solid-state electrolyte film and the color changing film, the barrier thin film comprises at least one layer which is formed by a material having a band gap energy, has a thickness of 7 nm to 7±2 nm, does not prevent ion conduction, and prevents carrier movement,

the color changing speed is 0.1 seconds to 0.3 seconds by a voltage driving.

(A4) A method for changing the color of a reversible color changing solid-state device comprising a solid-state electrolyte film and a color changing film, which reversibly changes the colored condition of the color changing film by irradiating a light and applying an electric field, wherein

a barrier thin film is inserted between the solid-state electrolyte film and the color changing film, the barrier thin film comprises at least one layer which is formed by a material having a band gap energy, has a thickness of 7 nm to 7±2 nm, does not prevent ion conduction, and prevents carrier movement,

the conductive property changing speed is 0.1 seconds to 0.3 seconds by a voltage driving.

(A5) A method for changing the conductive property of a reversible conductive property changing solid-state device comprising a solid-state electrolyte film and a conductive property changing film, which reversibly makes the conductive property changing film conductive or insulating by applying an electric field, wherein

a barrier thin film is inserted between the solid-state electrolyte film and the conductive property changing film, the barrier thin film comprises at least one layer which is formed by a material having a band gap energy, functions as a movement barrier for carriers, has a thickness of 7 nm to 7±2 nm,

the conducive property changing speed is 0.1 seconds to 0.3 seconds by a voltage driving.

(A6) A method for changing the conductive property of a reversible conductive property changing solid-state device comprising a solid-state electrolyte film and a conductive property changing film, which reversibly makes the conductive property changing film conductive by irradiating a light and makes the conducting conductive property changing film insulating by applying an electric field, wherein

a barrier thin film is inserted between the solid-state electrolyte film and the conductive property changing film, the barrier thin film comprises at least one layer which is formed by a material having a band gap energy, functions as a movement barrier for carriers, has a thickness of 7 nm to 7±2 nm,

the conducive property changing speed is 0.1 seconds to 0.3 seconds by a voltage driving.

### BRIEF DESCRIPTION OF THE DRAWINGS

FIG. 1 shows the structure and operation of a prior art EC device.

FIGS. 2(A), 2(B) show an energy band chart for the EC device shown in FIG. 1 when a solid-state electrolyte film is used as the electrolyte.

FIG. 2(A) shows the case where no voltage is applied between the acting electrode and the opposing electrode.

FIG. 2(B) shows the case where a forward voltage is applied between the acting electrode and the opposing electrode.

FIG. 3 shows the basic structure and operation of a reversible coloring and decoloring solid-state device, a reversible conductive property changing solid-state device and a reversible refractive index changing solid-state device according to the present invention.

FIG. 4(A) shows an energy band chart for the EC device in equilibrium, and (B) shows an energy band chart for the EC device when it is forward biased (coloring).

FIG. 5 shows the relationship between the thickness of the SiO₂ thin film and the coloring speed when the coloring drive voltage is 3V.

FIG. 6 shows an energy band chart for the EC device when the coloring is also performed by light excitation.

FIG. 7 shows an energy band chart for the EC device when it is reverse biased (decoloring).

FIG. 8 shows an embodiment (embodiment 1) of the reversible coloring and decoloring solid-state device according to the present invention.

FIG. 9 shows an energy band chart for the reversible coloring and decoloring solid-state device shown in FIG. 8.

FIG. 10 shows a temporal characteristic of the change of the transmission factor of the incoming light for the reversible coloring and decoloring solid-state device shown in FIG. 8.

FIG. 11 shows an embodiment (embodiment 2) of the reversible coloring and decoloring solid-state device according to the present invention for light excitation.

FIG. 12 shows an energy band chart for the reversible coloring and decoloring solid-state device shown in FIG. 11.

FIG. 13 shows a temporal characteristic of the change of the transmission factor of the incoming light for the reversible coloring and decoloring solid-state device shown in FIG. 12.

FIG. 14 shows an embodiment (embodiment 3) of the conducting path device (reversible conductive property changing solid-state device) according to the present invention.

FIG. 15 shows the time dependency of the sheet resistance when a voltage is applied to the conducting path device so that the acting electrode becomes the negative electrode and the opposing electrode becomes the positive electrode.

FIG. 16 shows an embodiment (embodiment 4) of the reversible refractive index changing solid-state device according to the present invention.

FIG. 17 shows a temporal characteristic of the change of the refractive index for the reversible refractive index changing solid-state device shown in FIG. 16.

FIG. 18 shows an embodiment (embodiment 5) of the light waveguide device according to the present invention, and the on condition of the device.

FIG. 19 shows the off condition of the light waveguide device shown in FIG. 18.

FIG. 20 shows an embodiment (embodiment 6) of the nonradiative display device (flat display) according to the present invention.

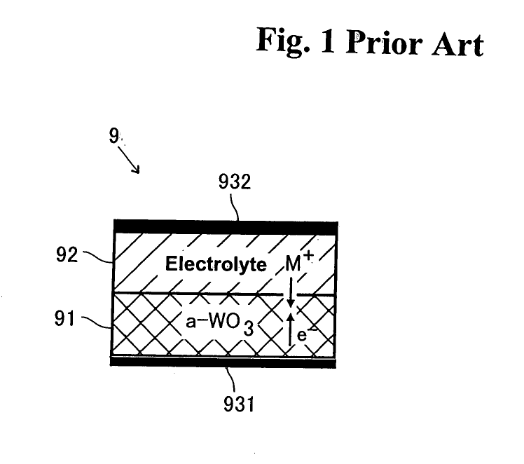

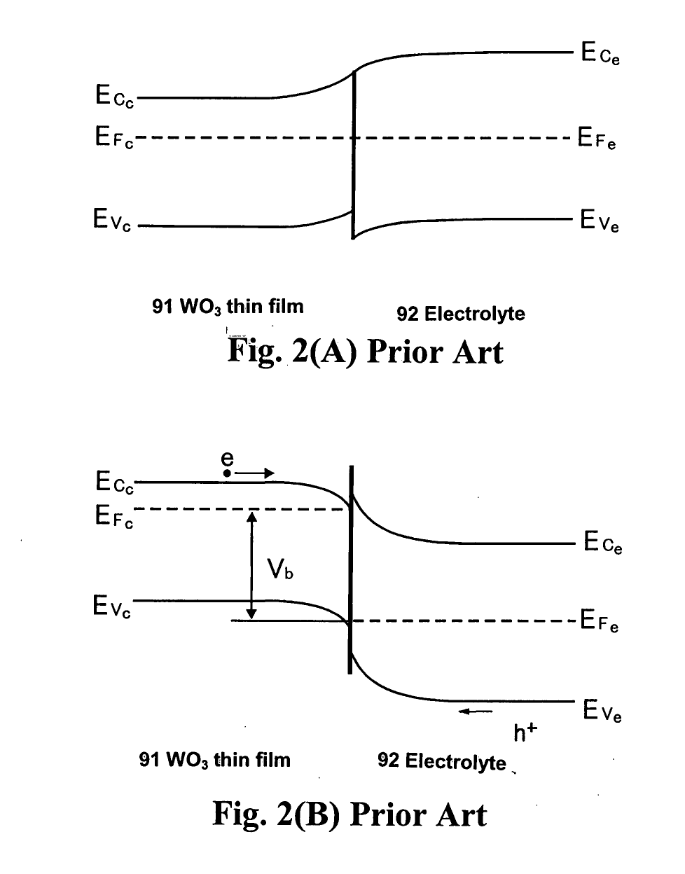

### DETAILED DESCRIPTION OF PREFERRED EMBODIMENTS

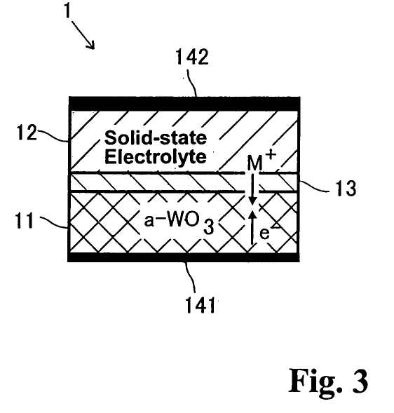

The basic structure and operation of a reversible coloring and decoloring solid-state device, a reversible conductive property changing solid-state device and a reversible refractive index changing solid-state device according to the present invention will be explained referring to FIG. 3. As the Electrochronomic (EC) device functions as a reversible coloring and decoloring solid-state device as well as a reversible conductive property changing solid-state device and a reversible refractive index changing solid-state device, the basic structure and operation of the EC device as a reversible coloring and decoloring solid-state device will be explained in FIG. 3.

In FIG. 3, the EC device 1 includes the barrier thin film 13 which is inserted between the coloring and decoloring film (a⁻WO₃ thin film) 11 and the solid-state electrolyte film 12. The barrier thin film 13 has a thickness in the range from 7 nm to 7±2 nm, and is formed by a material which has a band gap energy which is larger than that of either of the coloring and decoloring film 11 and the solid-state electrolyte film 12. The acting electrode 141 is formed on the surface of the coloring and decoloring film 11, and the opposing electrode 142 is formed on the surface of the solid-state electrolyte film 12.

According to the present invention, the coloring is driven at a voltage which provides a coloring speed from 0.1 seconds to 0.3 seconds. Specifically, the voltage at the time of coloring can be 3V.

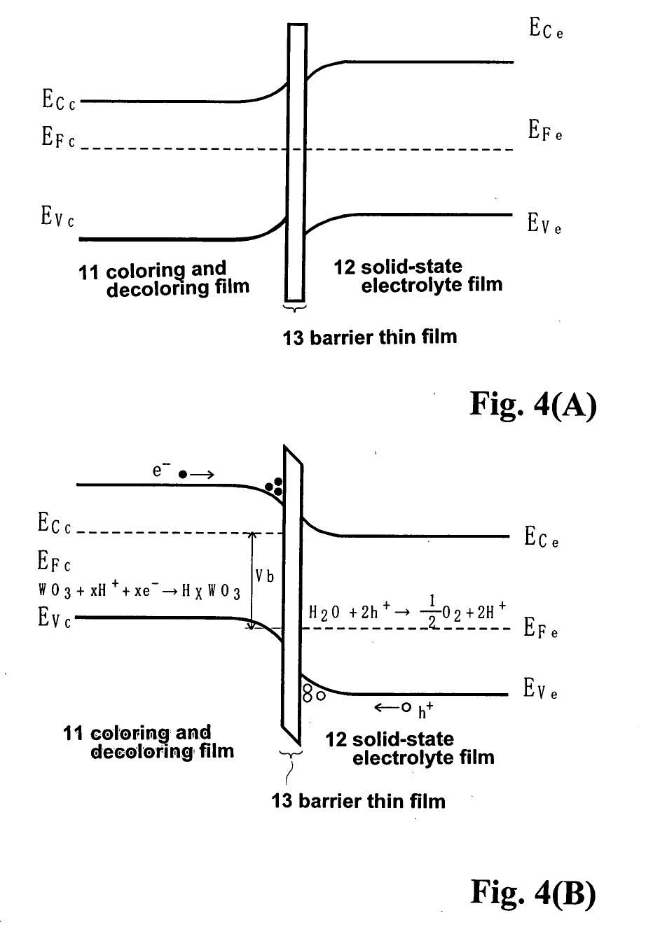

FIG. 4(A) shows an energy band chart for the EC device 1 in equilibrium. In this condition of equilibrium, a forward bias voltage V_{b} is applied in the direction which makes the acting electrode 141 the negative electrode and makes the opposing electrode 142 the positive electrode, the barrier thin film 13 becomes a great barrier for the holes h+ (a potential well is generated on the barrier thin film 13 side of the boundary face of the solid-state electrolyte film) as shown in FIG. 4 (b).

The holes h+ are accumulated and its density becomes high on the boundary face between the solid-state electrolyte film 12 and the barrier thin film 13 and the generation density of H+ by oxidization reaction. As a result of this operation, the coloring speed improves significantly.

As a result of a detail study, the inventors found that when the thickness of the SiO₂ thin film is from 7 nm to 7±2 nm, the coloring speed becomes significantly high because the accumulated holes h+contribute to the generation of the protons (H+) by priority, while the proton moves to WO₃ relatively easily by ion movement.

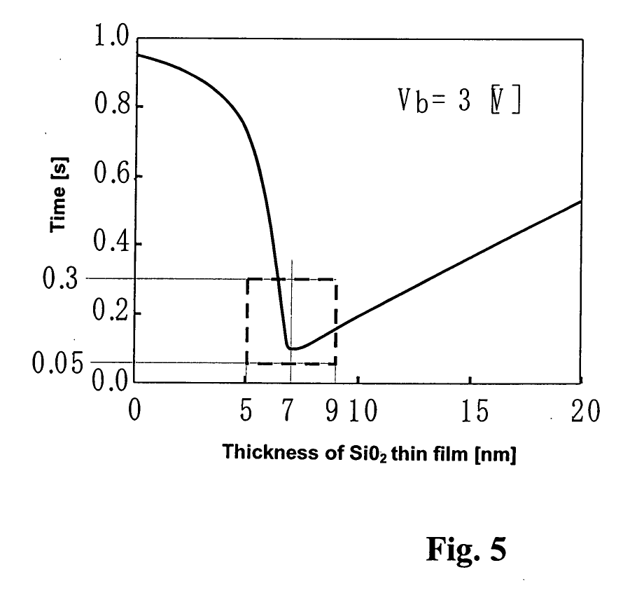

FIG. 5 shows the relationship between the thickness of the SiO₂ thin film and the coloring speed by actual measurement when the coloring drive voltage is 3V.

As the barrier by the barrier thin film 13 prevents the diffusion of electrons e⁻ to the side of the solid-state electrolyte film 12 and inhibits the diffusion of holes h+ to the side of the coloring and decoloring film 11, natural decoloring is inhibited, and therefore the maintenance performance of the color is improved.

That is to say, the diffusion of electrons to the side of the solid-state electrolyte and the diffusion of holes to the side of the WO₃ is inhibited at the same time by the barrier effect of SiO₂, therefore the decoloring by the backward reaction of the coloring is inhibited.

HxWO₃→xH⁺+xe⁻+WO₃

The EC device 1 can be colored by light excitation.

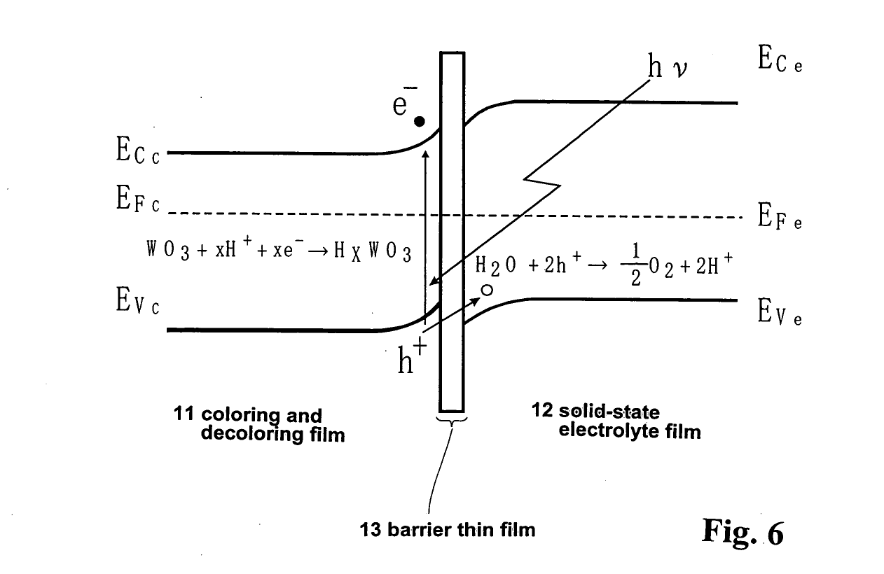

As shown in the energy band chart of FIG. 6, pairs of electron and hole are generated on the boundary face between the coloring and decoloring film 11 and the barrier thin film 13 by light excitation, and the holes h+ are accumulated on the boundary face between the solid-state electrolyte film 12 and the barrier thin film 13 and contribute to the generation of proton H+ by oxidization of water molecules H₂O, and the electron e⁻ are accumulated on the boundary face between the coloring and decoloring film 11 and the barrier film 13 and contribute the facilitation of diffusion of protons H+. As a result of this operation, the coloring speed by light excitation is significantly improved.

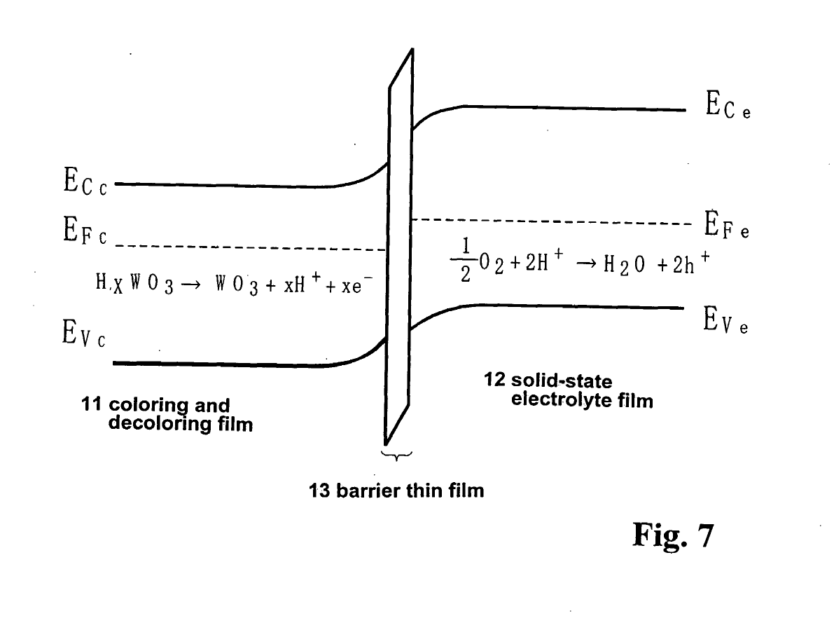

On the other hand, in the colored condition, when a reverse bias voltage Vb′ is applied in the direction that the acting electrode 141 is the positive electrode and the opposing electrode 142 is the negative electrode, the barrier thin film 13 becomes a great barrier for the electrons e⁻ as shown in FIG. 7. The electrons e⁻ are accumulated and its density becomes high on the on the boundary face between the solid-state electrolyte film 12 and the barrier thin film 13 and the reduction reaction of H+ is facilitated. As a result of this operation, the decoloring speed is significantly improved.

Although the material of the thin film 13 is formed form a material having a band gap energy which is larger than that of any material of the coloring and decoloring film 11 and the solid-sate electrolyte film 12 in this embodiment, other materials having an appropriate band gap energy can be selected depending on the purpose (whether faster or slower changing speed, etc.). The thickness of the thin film 13 is also adjusted depending on the material.

The barrier thin film 13 is formed by multiple layers (layers comprising the same compound or different kind of compounds). For example, it is formed by two SiO₂ layers having different properties. By this structure, the coloring and decoloring speed, the conductive property changing speed and the refractive index changing speed.

According to the present invention, as the coloring and decoloring film 11 or the conductive property changing film and the refractive index changing film, it is possible to use WO₃, an oxide of transition metal element M (for example, MoO₃, IrO₂, TiO₂, Nb₂O₅, V₂O₅, Rh₂O₃), a hydroxide (for example, NiOOH, CoOOH), a compound of M and chalcogen element X (S, Se, Te), i.e. MX, M₂X₃, MX₂, MX₃, MX₅, and their complex compound (for example, SrTiO₃, CaTiO₃), a perovskite structure material, a material which belongs to a intercalation compound, their mixed material, a nitride, e.g. In, Sn, an organic material, e.g. a diphthalocyanine complex, a heptylviologen.

According to the present invention, as the solid-state electrolyte film 12, it is possible to use Ta₂O₅, an oxide, e.g. Cr₂O₃, high ion conductive CaF₂, AgI, β alumina, and ion conducting polymer molecule.

According to the present invention, as the barrier thin film 13, it is possible to use SiO₂, LiOx, LiNx, NaOx, KOx, RbOx, CsOx, BeOx, MgOx, MgNx, CaOx, CaNx, Srx, aOx, ScOx, YOx, YNx, LaOx, LaNx, CeOx, PrOx, NdOx, SmOx, EuOx, GdOx, TbOx, DyOx, HoOx, ErOx, TmOx, YbOx, LuOx, TiOx, TiNx, ZrOx, ZrNx, HfOx, HfNx, ThOx, VOx, VNx, NbOx, NbNx, TaOx, TaNx, CrOx, CrNx, MoOx, MoN, WOx, WNx, MnOx.

### Embodiment 1

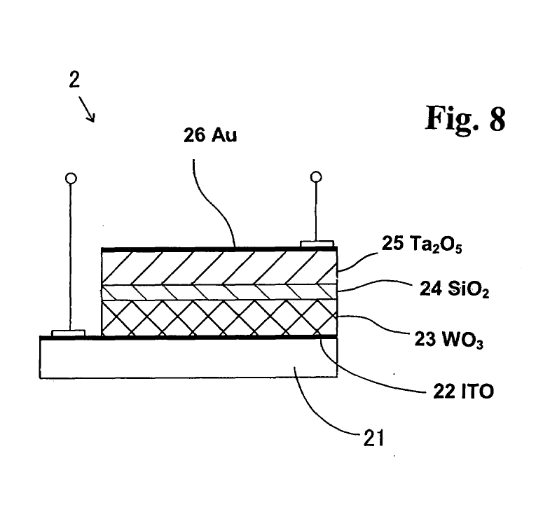

One embodiment of a reversible coloring and decoloring solid-state device (EC device) according to the present invention will be explained referring to FIG. 8. In FIG. 8, the reversible coloring and decoloring solid-state device 2 is formed by stacking the deposited acting electrode 22 (ITO) on the glass substrate 21, the coloring and decoloring film 23 on the acting electrode 22, the barrier thin film 24 on the coloring and decoloring film 23, the solid-state electrolyte film 25 on the barrier thin film 24, and the opposing electrode (Au film) 26 on the solid-state electrolyte film 25.

WO₃ is deposited as the coloring and decoloring film 23 by the RF sputtering method, and SiO₂ is deposited as the barrier thin film 24 using the RF sputtering method.

Ta₂O₅ (source of supplying hydrogen ions H+) is deposited as the solid-state electrolyte film 25 by the EB vapor deposition. Although oxide tantalum Ta₂O₅ is dielectric, since a slight amount of water molecules absorbed in the film generate hydrogen ions, oxide tantalum Ta₂O₅ functions as a solid-state electrolyte.

The film forming condition for the coloring and decoloring film 23 (WO₃ film) is:

Substrate temperature: room temperature
Sputtering atmosphere: Ar/O₂ mixed gas (ratio 1:1)
Supplied power: 50 W
Degree of vacuum during film formation: 15 mTorr,
and 300 nm WO₃ film was formed in this embodiment.

The film forming condition for the barrier thin film 24 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
and 7 nm SiO₂ film was formed in this embodiment.

The film forming condition for the solid-state electrolyte film 25 (Ta₂O₅ film) is:

Substrate temperature: 60° C. or lower
Evaporation speed: 0.07 nm/s
and 400 nm Ta₂O₅ film was formed in this embodiment.

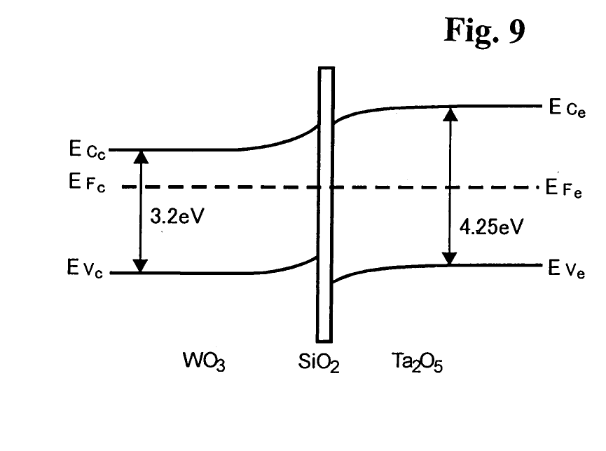

The band gap energy (Eg) is 3.2 eV for WO₃, 4.25 eV for Ta₂O₅ and 6-8 eV for SiO₂ (it depends on the film quality, high for a single crystal and low for an amorphous condition), FIG. 9 shows an energy band chart for the condition before an electric field is applied. When an external voltage is applied in this condition, the barrier thin film 24 (SiO₂ film) becomes a barrier for holes h+. The holes h+are accumulated on the boundary face of the barrier thin film 24 and the solid-state electrolyte film 25 (Ta₂O₅/SiO₂ joint surface) and its density becomes high, and it facilitates the oxidization of water molecules and increases the density of H+.

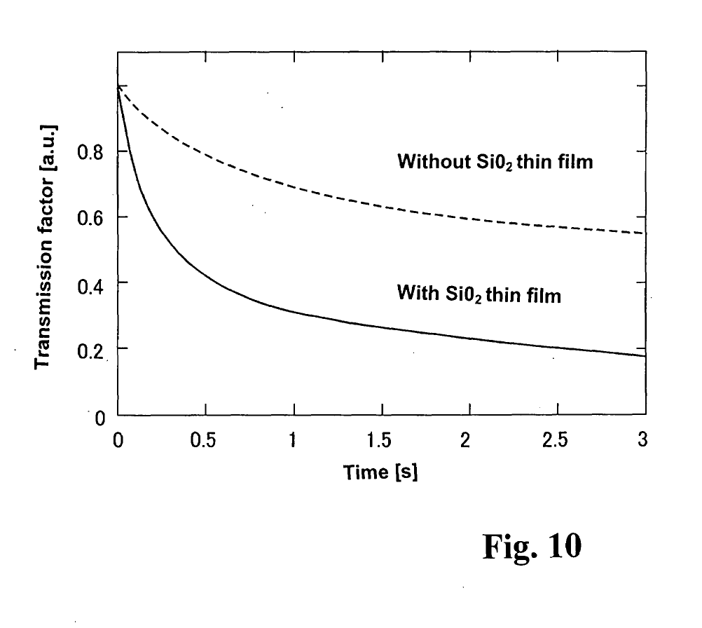

The barrier inhibits the reverse reaction, or decoloring. By this operation, the speed of coloring to blue becomes significantly high by the generation of H×WO₃. In this embodiment, a voltage which provides the coloring speed of 0.1 seconds to 0.3 seconds is used for coloring. Specifically, the voltage of 3V is applied to the reversible coloring and decoloring solid-state device 2 by the polarity shown in FIG. 4(B) so that the acting electrode 22 becomes the negative electrode and the opposing electrode 26 becomes the positive electrode, and the time dependency of the coloring is measured by changing the transmission factor of the incoming light. The measurement result is shown in FIG. 10 in full line. In FIG. 10, the measurement result for the reversible coloring and decoloring solid-state device which has no barrier thin film 24 (SiO₂ film) is shown with a dotted line for comparison.

As shown in FIG. 10, while the time for decreasing the transmittance to 70% of the initial value for the reversible coloring and decoloring solid-state device having no barrier thin film 24 (SiO₂ film) is 1 second, the time is shorten to 120 ms in this embodiment, and the coloring and decoloring response speed of the reversible coloring and decoloring solid-state device 2 improved to the practical level.

### Embodiment 2

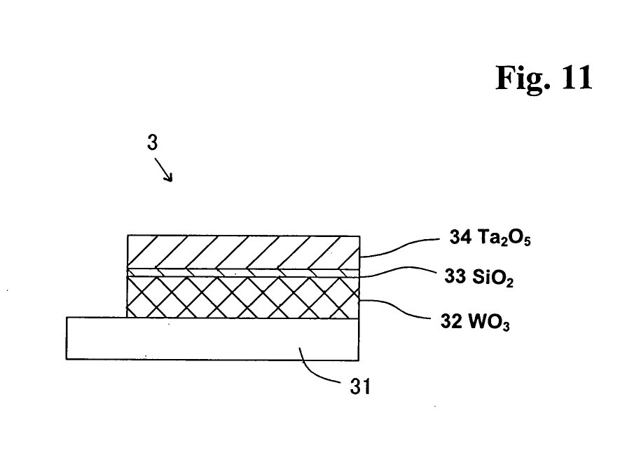

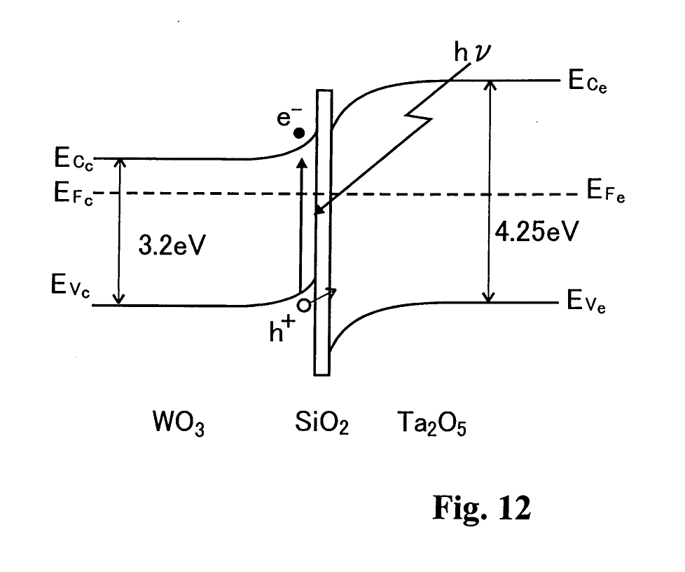

One embodiment of a reversible coloring and decoloring solid-state device by light excitation according to the present invention will be explained referring to FIG. 11. In FIG. 11, the reversible coloring and decoloring solid-state device 3 is formed by stacking the coloring and decoloring film 32 on the glass substrate 31, the barrier thin film 33 on the coloring and decoloring film 32, the solid-state electrolyte film 34 on the barrier thin film 33.

WO₃ is deposited as the coloring and decoloring film 32 by the RF sputtering method, and a SiO₂ thin film is deposited as the barrier thin film 33 using the RF sputtering method. Ta₂O₅ is deposited as the solid-state electrolyte film 34 by the EB vapor deposition.

The film forming condition for the coloring and decoloring film 32 (WO₃ film) is:

Substrate temperature: room temperature
Sputtering atmosphere: Ar/O₂ mixed gas (ratio 1:1)
Supplied power: 50 W
Degree of vacuum during film formation: 15 mTorr,
and 300 nm WO₃ film was formed in this embodiment.

The film forming condition for the barrier thin film 33 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
and 7 nm SiO₂ film was formed in this embodiment.

The film forming condition for the solid-state electrolyte film 34 (Ta₂O₅ film) is:

Substrate temperature: 60° C. or lower
Evaporation speed: 0.07 nm/s
and 400 nm Ta₂O₅ film was formed in this embodiment.

The band gap energy (Eg) is 3.2 eV for WO₃, 4.25 eV for Ta₂O₅ and 6-8 eV for SiO₂. FIG. 9 shows an energy band chart for the condition before light irradiation. In this condition, pairs of electron and holes are generated on the boundary face of the barrier thin film 33 and the solid-state electrolyte film 34 (Ta₂O₅/SiO₂ joint surface) by light excitation. The holes h+contribute to the generation of protons by oxidization of water molecules. The electrons e⁻ contribute to diffusion of protons by accumulation on the boundary face. By this operation, the speed of coloring to blue becomes significantly high by the generation of H×WO₃.

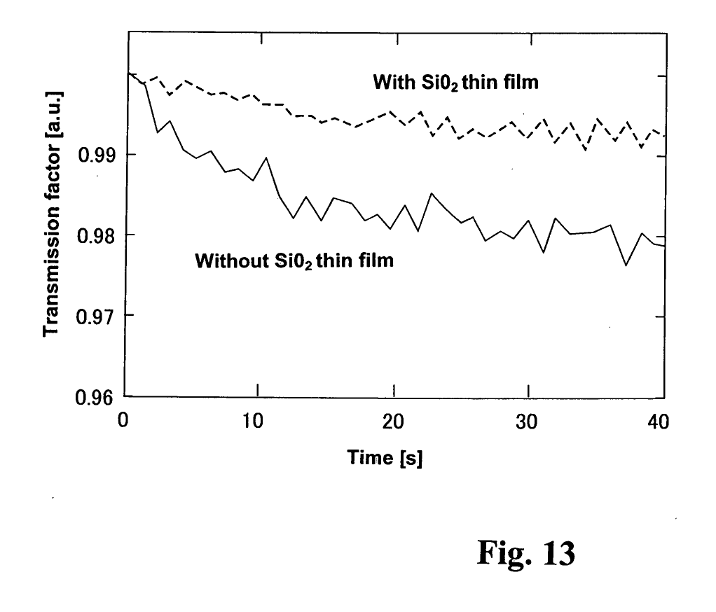

Xe lamp light is irradiated to this device and the measurement result of the time dependency of the coloring by changing the transmission of the incoming light is shown in FIG. 13 in full line. In this embodiment, a voltage which provides the coloring speed of 0.1 seconds to 0.3 seconds is used for coloring. Specifically, the voltage of 3V is applied to the reversible coloring and decoloring solid-state device 3 by the polarity shown in FIG. 4(B) so that the acting electrode 22 becomes the negative electrode and the opposing electrode 26 becomes the positive electrode, and the time dependency of the coloring is measured by changing the transmission factor of the incoming light. The measurement result is shown in FIG. 13 in full line. In FIG. 13, the measurement result for the reversible coloring and decoloring solid-state device which has no barrier thin film (SiO₂ film) is shown with a dotted line for comparison.

As shown in FIG. 13, the coloring speed of this light excited device becomes significantly faster than a device having no SiO₂.

### Embodiment 3

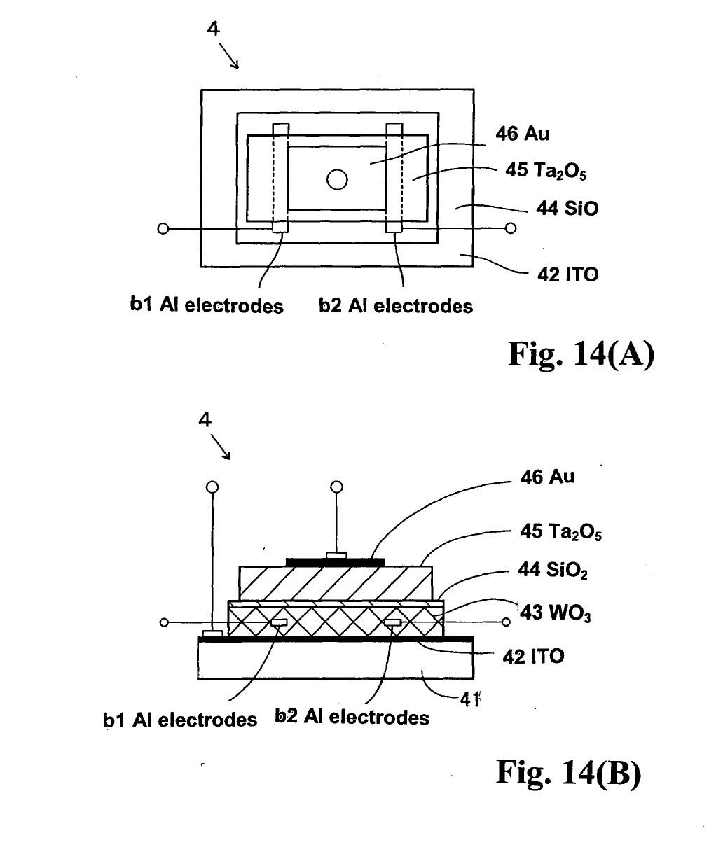

One embodiment of a conducting path device (a switching device (a reversible conductive property changing solid-state device)) according to the present invention will be explained referring to FIG. 14. In FIG. 14, the conducting path device 4 is formed by stacking the deposited acting electrode 42 (ITO) on the glass substrate 41, the conductive property changing film 43 on the acting electrode 42, the barrier thin film 44 on the conductive property changing film 43, the solid-state electrolyte film 45 on the barrier thin film 44, and the opposing electrode (Au film) 46 on the solid-state electrolyte film 45. Al electrodes b1, b2 are formed on the conductive property changing film 43 for resistance measurement.

WO₃ is deposited as the conductive property changing film 43 by the RF sputtering method, and a SiO₂ thin film is deposited as the barrier thin film 44 using the RF sputtering method. Ta₂O₅ (source of supplying hydrogen ions H+) is deposited as the solid-state electrolyte film 45 by the EB vapor deposition.

The film forming condition for the conductive property changing film 43 (WO₃ film) is:

Substrate temperature: room temperature
Sputtering atmosphere: Ar/O₂ mixed gas (ratio 1:1)
Supplied power: 50 W

Degree of vacuum during film formation: 15 mTorr,

and 300 nm WO₃ film was formed in this embodiment.

The film forming condition for the barrier thin film 44 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
and 7 nm SiO₂ film was formed in this embodiment.

The film forming condition for the solid-state electrolyte film 45 (Ta₂O₅ film) is:

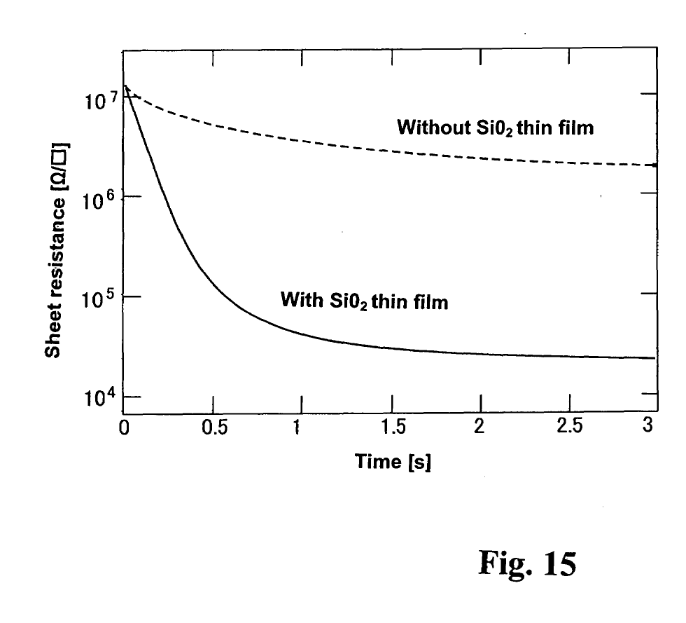

Substrate temperature: 60° C. or lower
Evaporation speed: 0.07 nm/s
and 400 nm Ta₂O₅ film was formed in this embodiment.
Al electrodes b1, b2 are deposited to the thickness of 300 nm by a vapor deposition method and they are buried in the conductive property changing film 43 (WO₃ film). The voltage of 3V is applied to the conducting path device 4 by the polarity shown in FIG. 14 so that the acting electrode 42 becomes the negative electrode and the opposing electrode 46 becomes the positive electrode, and the time dependency of the sheet resistance is measured. The measurement result is shown in FIG. 15 in full line. In this embodiment, a voltage which provides the conductive property speed of 0.1 seconds to 0.3 seconds is used. In FIG. 15, the measurement result for the conducting path device (reversible conductive property changing solid-state device which has no barrier thin film 44 (SiO₂ film) is shown with a dotted line for comparison.

As shown in FIG. 15, the change of the sheet resistance of the conductive property changing film 43 (WO₃ film) becomes significantly faster than a reversible conductive property changing solid-state device having no barrier thin film 44 (SiO₂ film). The above described conducting path device 4 can be formed on a glass substrate in arbitrary pattern, and a semiconductor substrate or a plastic substrate can be used in place of a glass substrate.

### Embodiment 4

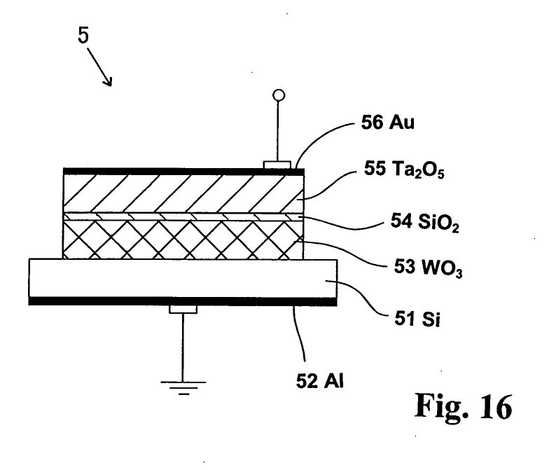

One embodiment of a reversible refractive index changing solid-state device according to the present invention will be explained referring to FIG. 16. In FIG. 16, the reversible refractive index changing solid-state device 5 is formed by stacking the deposited acting electrode 52 (Al film) on the SiO₂ substrate 51, the refractive index changing film 53 on the acting electrode 42, the barrier thin film 54 on the refractive index changing film 53, the solid-state electrolyte film 55 on the barrier thin film 54, and the opposing electrode (Au film) 56 on the solid-state electrolyte film 55.

WO₃ is deposited as the refractive index changing film 53 by the RF sputtering method, and a SiO₂ thin film is deposited as the barrier thin film 54 using the RF sputtering method. Ta₂O₅ (source of supplying hydrogen ions H+) is deposited as the solid-state electrolyte film 55 by the EB vapor deposition.

The film forming condition for the refractive index changing film 53 (WO₃ film) is:

Substrate temperature: room temperature
Sputtering atmosphere: Ar/O₂ mixed gas (ratio 1:1)
Supplied power: 50 W
Degree of vacuum during film formation: 15 mTorr,
and 300 nm WO₃ film was formed in this embodiment.

The film forming condition for the barrier thin film 54 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
and 7 nm SiO₂ film was formed in this embodiment.

The film forming condition for the solid-state electrolyte film 55 (Ta₂O₅ film) is:

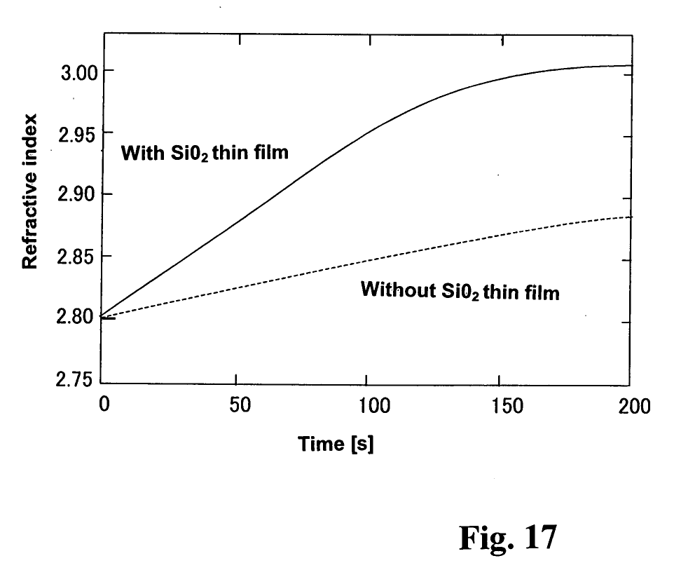

Substrate temperature: 60° C. or lower
Evaporation speed: 0.07 nm/s
and 400 nm Ta₂O₅ film was formed in this embodiment.
The voltage of 3V is applied to the refractive index changing solid-state device 5 by the polarity shown in FIG. 16 so that the acting electrode 52 becomes the negative electrode and the opposing electrode 56 becomes the positive electrode, and the time dependency of the refractive index change is measured. The measurement result is shown in FIG. 17 in full line. In this embodiment, a voltage which provides the refractive index changing speed of 0.1 seconds to 0.3 seconds is used. In FIG. 17, the measurement result for the reversible refractive index changing solid-state which has no barrier thin film (SiO₂ film) is shown with a dotted line for comparison.

As shown in FIG. 17, the refractive index changing speed of the refractive index changing film (WO₃) in the reversible refractive index changing solid-state device 5 becomes significantly faster than a device having no barrier film (SiO₂ film), and the refractive index rapidly returns to the original refractive index by applying a voltage of the reverse polarity (the acting electrode 52 is the positive electrode, and the opposing electrode 56 is the negative electrode).

### Embodiment 5

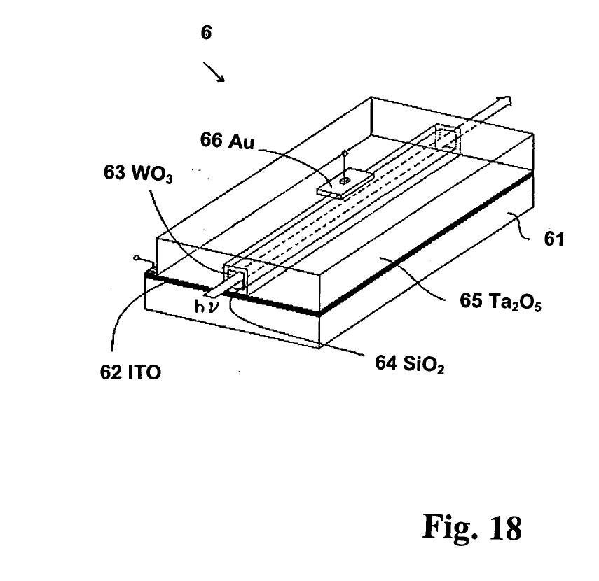

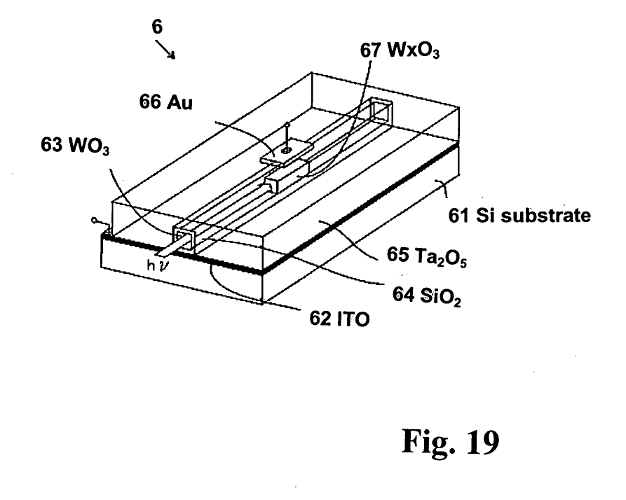

One embodiment of a light waveguide device (a light switching device) according to the present invention will be explained referring to FIGS. 18 and 19. In FIGS. 18 and 19, the light waveguide device 6 is formed by the following process. A thin line pattern of SiO₂ is formed by photolithography on the glass substrate 61 with the acting electrode 62 (ITO) deposited on it. The refractive index changing film 63 (WO₃) is deposited by sputtering on the thin line pattern of SiO₂. SiO₂ is formed by RF sputtering on the thin line pattern part of the refractive index changing film 63 (WO₃). By this process a light waveguide of a thin line shape is formed by coating the refractive index changing film 63 (WO₃) with the barrier thin film 64 (SiO₂). The solid-state electrolyte film 65 (Ta₂O₆) is deposited by EB vapor deposition so that the light waveguide is buried, and the opposing electrode (Au film) 66 is stacked on it. The width of the formed light waveguide is 200 μm.

The film forming condition for the refractive index changing film 63 (WO₃ film) is:

Substrate temperature: room temperature
Sputtering atmosphere: Ar/O₂ mixed gas (ratio 1:1)
Supplied power: 50 W
Degree of vacuum during film formation: 15 mTorr,
A film of 2 μm thickness was formed in this embodiment.

The film forming condition for the barrier thin film 44 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
A film of about 7 nm thickness was formed in this embodiment.

The film forming condition for the solid-state electrolyte film 45 (Ta₂O₅ film) is:

Substrate temperature: 60° C. or lower
Evaporation speed: 0.07 nm/s
A film of about 3 μm thickness was formed in this embodiment.

Since the refractive index of Ta₂O₅ (2.1) is smaller than that of WO₃ (2.8), the refractive index changing film 63 (WO₃ film) functions as the core layer of a light waveguide, and the solid-state electrolyte film 65 (Ta₂O₅ film) functions as the cladding layer. Therefore, when the He—Ne laser light (h ν) which was condensed by a lens is irradiated on one end face of the light waveguide device 6, the light propagates in the refractive index changing film 63 and exits from the opposing end face. That is to say, the light waveguide device 6 is in ON state of a light switch (See FIG. 18).

When a forward bias voltage of 3V is applied between the acting electrode 62 and the opposing electrode 66 so that the acting electrode 42 becomes the negative electrode and the opposing electrode 46 becomes the positive electrode, the refractive index changing film 63 (WO₃ film) is colored and the transmission factor of the incoming light becomes low. By this operation, the light is substantially is blocked and the light waveguide device 6 enters in OFF state of a light switch (See FIG. 19). When a voltage of the reverse polarity I applied to the Au thin film, the colored portion is easily decolored and returned to the original transparent, and the light waveguide passes the light again and the light waveguide device 6 enters in ON state.

In this embodiment, a voltage which provides the refraction index changing speed of 0.1 seconds to 0.3 seconds is used. Specifically, the voltage of 3V is applied to the light waveguide device 6 by the polarity shown in FIG. 4(B) so that the acting electrode 22 becomes the negative electrode and the opposing electrode 26 becomes the positive electrode, and the time dependency of the refractive index change was measured.

The refractive index of the refractive index changing film 63 can be controlled by the aforementioned application of an electric field. The light waveguide device 6 can be formed on the glass substrate 61 in an arbitrary pattern. The light waveguide device 6 can also be formed on a semiconductor substrate or a plastic substrate in an arbitrary pattern

### Embodiment 6

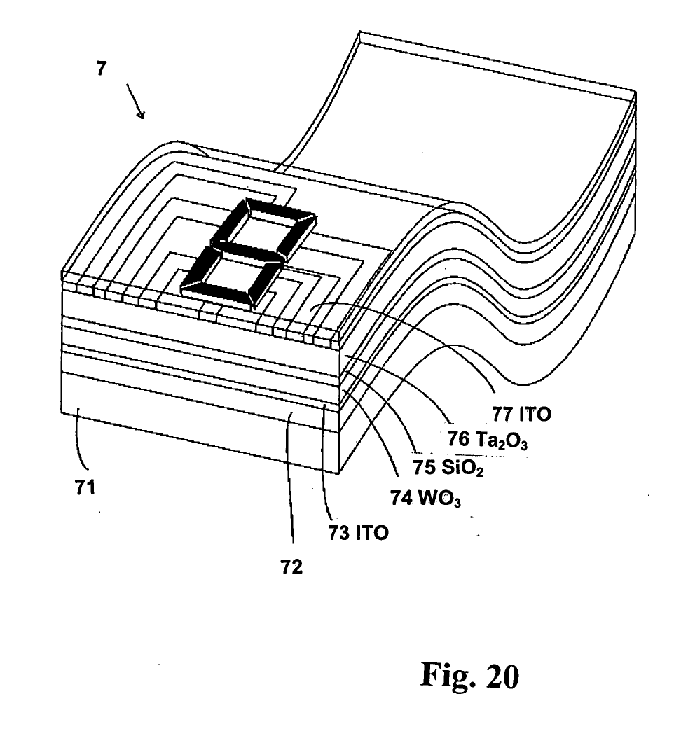

One embodiment of a nonradiative display device according to the present invention will be explained referring to FIG. 20. In FIG. 20, the nonradiative display device 7 is formed by stacking the white background thin film 72 on the plastic substrate 71, the acting electrode 73 on the white background thin film 72, the coloring and decoloring film 74 on the acting electrode 73, the barrier thin film 75 on the coloring and decoloring film 74, the solid-state electrolyte film 76 on the barrier thin film 75, and the opposing electrode 77 on the solid-state electrolyte film 76.

In this embodiment, a polyimide film is used as the plastic substrate 71, porous Al₂O₃ is deposited on the plastic substrate 71 as the white background thin film 72, and a transparent electrode (ITO thin film) is deposited on the white background thin film 72 as the acting electrode 73. Next, WO₃ is deposited by RF sputtering as the coloring and decoloring film 74, and a thin line pattern of WO₃ is formed by removing the mask. Then, SiO₂ is deposited by RF sputtering as the barrier thin film 75, and Ta₂O₅ is deposited by EB vapor deposition as the solid-state electrolyte film 76.

The film forming condition for the coloring and decoloring film 74 (WO₃ film) is:

Substrate temperature: room temperature
Sputtering atmosphere: Ar/O₂ mixed gas (ratio 1:1)
Supplied power: 50 W
Degree of vacuum during film formation: 15 mTorr,
300 nm WO₃ film was formed in this embodiment.

The film forming condition for the barrier thin film 75 (SiO₂ film) is:

Substrate temperature: room temperature
Sputtering atmosphere: Ar/O₂ mixed gas (ratio 1:1)
Supplied power: 50 W
Degree of vacuum during film formation: 15 mTorr,
7 nm SiO₂ film was formed in this embodiment.

The film forming condition for the solid-state electrolyte film 76 (Ta₂O₅ film) is:

Substrate temperature: 60° C. or lower
Evaporation speed: 0.07 nm/s
400 nm Ta₂O₅ film was formed in this embodiment.

A transparent electrode ITO thin film is used for the acting electrode 77, and the stripes of the contact portion for electric input and the segments of the display portion are formed in a pattern. In this embodiment, a voltage which provides the coloring speed of 0.1 seconds to 0.3 seconds is used for coloring. Specifically, the voltage of 3V is applied to the nonradiative display device 7 by the polarity shown in FIG. 4(B) so that the acting electrode 22 becomes the negative electrode and the opposing electrode 26 becomes the positive electrode, and a reflective display is obtained.

It is confirmed that a numeric characters can be displayed by a dark blue font on the white background by selecting the corresponding 7 segments and controlling the address signal in the direction that a voltage is applied for the electrode on the substrate side. The nonradiative display device 8 operates at a low voltage and has a enough high contrast and response speed for a display. Since the substrate is quite flexible and all elements are configured by the solid-state thin film, this device can be used as a paper like display of a super thin thickness and light weight.

### INDUSTRIAL APPLICABILITY

By inserting a thin film barrier layer between the coloring and decoloring film and the ion supplying thin film, the coloring efficiency and response speed is significantly improved while the all configurations of the EC device is formed by solid-state thin films.

While the invention has been explained with reference to the specific embodiments of the invention, the explanation is illustrative and the invention is limited only by the appended claims.

1. A reversible coloring and deccoloring solid-state device comprising a solid-state electrolyte film and a coloring and decoloring film which colors or decolors the coloring and decoloring film reversibly by applying an electric field, wherein
a barrier thin film is inserted between the solid-state electrolyte film and the coloring and decoloring film, the barrier thin film comprises at least one layer which is formed by a material having a band gap energy, functions as a barrier for the carrier movement, has a thickness of 7 nm to 7±2 nm which does not prevent ion conduction,
the coloring and decoloring speed is 0.1 seconds to 0.3 seconds by a voltage driving.

2. (canceled)

3. A reversible coloring and deccoloring solid-state device comprising a solid-state electrolyte film and a coloring and decoloring film which reversibly colors and decolors the coloring and decoloring film by irradiating a light, wherein
a barrier thin film being inserted between the solid-state electrolyte film and the coloring and decoloring film, the barrier thin film comprises at least one layer which is formed by a material having a band gap energy,
the barrier thin film has a thickness of the range between 7 nm and 7±2 nm,
the device is driven by a voltage so that the coloring speed is from 0.1 seconds to 0.3 seconds.

4. (canceled)

5. A reversible color changing solid-state device comprising a solid-sate electrolyte film and a color changing film, and changing the colored condition of the color changing film reversibly by applying an electric field, wherein
a barrier thin film is inserted between the solid-state electrolyte film and the color changing film, the barrier thin film comprises at least one layer which is formed by a material having a band gap energy, functions as a barrier for the carrier movement, has a thickness of 7 nm to 7±2 nm which does not prevent ion conduction,
the color changing speed is 0.1 seconds to 0.3 seconds by a voltage driving.

6. (canceled)

7. A reversible color changing solid-state device comprising a solid-sate electrolyte film and a color changing film, and changing the colored condition of the color changing film reversibly by irradiating a light and applying an electric field, wherein
a barrier thin film is inserted between the solid-state electrolyte film and the color changing film, the barrier thin film comprises at least one layer which is formed by a material having a band gap energy, functions as a barrier for the carrier movement, and has a thickness of 7 nm to 7±2 nm which does not prevent ion conduction,
the color changing speed is 0.1 seconds to 0.3 seconds by a voltage driving.

8. (canceled)

9. A reversible conductive property changing solid-state device comprising a solid-sate electrolyte film and a conductive property changing film, and making the conductive property changing film conductive or insulating reversibly by applying an electric field, wherein
a barrier thin film being inserted between the solid-state electrolyte film and the conductive property changing film, the barrier thin film comprises at least one layer which is formed by a material having a band gap energy, functions as a barrier for the carrier movement, and has a thickness of 7 nm to 7±2 nm,
the conductive property changing speed is 0.1 seconds to 0.3 seconds by a voltage driving.

10. (canceled)

11. A reversible conductive property changing solid-state device comprising a solid-sate electrolyte film and a conductive property changing film, and making the conductive property changing film conductive by irradiating a light and making the conductive property changing film insulating by applying an electric field reversibly, wherein
a barrier thin film being inserted between the solid-state electrolyte film and the conductive property changing film, the barrier thin film comprises at least one layer which is formed by a material having a band gap energy, functions as a barrier for the carrier movement, and has a thickness of 7 nm to 7±2 nm,
the conductive property changing speed is 0.1 seconds to 0.3 seconds by a voltage driving.

12-16. (canceled)

17. A reversible refractive index changing solid-state device comprising a solid-sate electrolyte film and a refractive index changing film, and reversibly changing the refractive index of the refractive index changing film from a first refractive index to a second refractive index or from the second refractive index to the first refractive index reciprocally by applying an electric field, wherein
a barrier thin film being inserted between the solid-state electrolyte film and the refractive index changing film, the barrier thin film comprises at least one layer which is formed by a material having a band gap energy, functions as a barrier for the carrier movement, and has a thickness of 7 nm to 7±2 nm,
the refractive index changing speed is 0.1 seconds to 0.3 seconds by a voltage driving.

18-24. (canceled)

25. A nonradiative display device, wherein the reversible coloring and decoloring solid-state device according to claim 1 is formed on a semiconductor substrate, a glass substrate or a plastic substrate as an array, the reversible coloring and decoloring solid-state device or a group of the coloring and decoloring solid-state devices is used as one pixel.

26. A conducting path device, wherein the reversible conductive property changing solid-state device according to claim 9 is formed on a semiconductor substrate, a glass substrate or a plastic substrate in an arbitrary pattern,
the conductive property of the conductive property changing film is controlled by applying an electric field.

27. A conducting path device, wherein the reversible conductive property changing solid-state device according to claim 11 is formed on a semiconductor substrate, a glass substrate or a plastic substrate in an arbitrary pattern,
the conductive property of the conductive property changing film is controlled by irradiating a light and applying an electric field.

28. A light waveguide device, wherein the reversible refractive index changing solid-state device according to claim 17 is formed on a semiconductor substrate, a glass substrate or a plastic substrate in an arbitrary pattern,
the refractive index changing film is formed as a core layer of the light waveguide and the refractive index of the refractive index changing film is controlled by applying an electric field.

29. (canceled)
